(19) United States
(12) Patent Application Publication
(10) Pub. No.: US 2026/0082571 A1
(43) Pub. Date: Mar. 19, 2026

(54) STORAGE DEVICE

(71) Applicant: Kioxia Corporation, Tokyo (JP)

(72) Inventors: Tomoya SANUKI, Yokkaichi Mie (JP); Tatsuya FUJISHIMA, Yokkaichi Mie (JP); Keisuke NAKATSUKA, Kuwana Mie (JP); Masaru KITO, Kuwana Mie (JP)

(73) Assignee: Kioxia Corporation, Tokyo (JP)

(21) Appl. No.: 19/066,398

(22) Filed: Feb. 28, 2025

(30) Foreign Application Priority Data
Sep. 13, 2024 (JP) 2024-159550

(51) Int. Cl. H10B 43/40; G11C 16/26; H01L 23/00; H01L 25/065; H01L 25/18; H10B 41/27; H10B 41/41; H10B 43/27; H10B 80/00

(52) U.S. Cl. CPC H10B 43/40; G11C 16/26; H10B 41/27; H10B 41/41; H10B 43/27; H10B 80/00; H10W 90/00; H10W 90/792

(57) ABSTRACT

A storage device includes a memory cell array and a peripheral circuit, wherein a first circuit of the peripheral circuit includes a first transistor, a second transistor, a trench, a first insulating layer, and a second insulating layer. The first transistor is connected to a first word line via first and fourth connecting electrodes, and the second transistor is connected to a second word line via second and fifth connecting electrodes. The trench is arranged in a first semiconductor layer between the first and second transistors, the first insulating layer is formed in the trench, the second circuit is connected to a bit line via third and sixth connecting electrodes, and the second insulating layer is in contact with the first insulating layer at an end portion on a side further from a memory cell array.

### CROSS REFERENCE TO RELATED APPLICATIONS

This application is based upon and claims the benefit of priority from the prior Japanese Patent Application No. 2024-159550, filed on Sep. 13, 2024, the entire contents of which are incorporated herein by reference.

### FIELD

An embodiment of the present disclosure relates to a storage device.

### BACKGROUND

A storage device including a plurality of transistors formed on a semiconductor substrate is known. The storage device includes a memory cell array and a peripheral circuit. In the memory cell array, an increase in the number of stacked layers in a multi-layer wiring structure used as a word line, and an increase in the number of bits for a single memory cell in order to make the memory cell multi-valued are required to reduce the arrangement area and increase the density of the storage device. On the other hand, with the increase in the speed of an input/output circuit, the performance of the peripheral circuit is required to be improved. Therefore, there is a problem that it is difficult to reduce the size of the peripheral circuit.

In order to solve this problem, in recent years, a CBA (CMOS directly Bonded to Array) process has been developed in which a memory wafer on which a memory cell array is formed and a CMOS wafer on which a peripheral circuit is formed are separately formed and wirings arranged on these wafers are bonded to each other to form a memory chip.

### BRIEF DESCRIPTION OF DRAWINGS

FIG. 1 is a block diagram for explaining a configuration of a storage device according to an embodiment.

FIG. 2 is a diagram for describing an equivalent circuit showing a configuration of a memory cell array of a storage device according to an embodiment.

FIG. 3 is a diagram for explaining a circuit configuration of a sense amplifier module of a storage device according to an embodiment.

FIG. 4 is a diagram for explaining a circuit configuration of a row decoder of a storage device according to an embodiment.

FIG. 5 is a cross-sectional view showing an outline of a storage device according to an embodiment.

FIG. 6 is a cross-sectional view showing an outline of a storage device according to an embodiment.

FIG. 7 is a cross-sectional view showing an outline of a storage device according to a comparative embodiment.

FIG. 8 is a cross-sectional view showing an outline of a storage device according to an embodiment.

FIG. 9 is a cross-sectional view showing an outline of a storage device according to an embodiment.

FIG. 10 is a cross-sectional view illustrating a method for manufacturing a storage device according to an embodiment.

FIG. 11 is a cross-sectional view illustrating a method for manufacturing a storage device according to an embodiment.

FIG. 12 is a cross-sectional view showing an outline of a storage device according to an embodiment.

FIG. 13 is a cross-sectional view illustrating a method for manufacturing a storage device according to an embodiment.

FIG. 14 is a cross-sectional view illustrating a method for manufacturing a storage device according to an embodiment.

FIG. 15 is a cross-sectional view showing an outline of a storage device according to an embodiment.

FIG. 16 is a cross-sectional view illustrating a method for manufacturing a storage device according to an embodiment.

FIG. 17 is a cross-sectional view illustrating a method for manufacturing a storage device according to an embodiment.

FIG. 18 is a diagram for explaining a circuit configuration of a sense amplifier module of a storage device according to an embodiment.

### DESCRIPTION OF EMBODIMENTS

A storage device according to an embodiment of the present invention includes: a memory cell array; and a peripheral circuit, wherein the memory cell array includes: a first memory cell; a second memory cell; a first word line connected to the first memory cell; a second word line connected to the second memory cell; a bit line connected to the first memory cell and the second memory cell; a first connecting electrode; a second connecting electrode; and a third connecting electrode, the peripheral circuit includes: a first circuit; a second circuit; a third circuit connected to the first circuit and the second circuit and configured to send/receive a signal to/from an external device; a fourth connecting electrode bonded to the first connecting electrode; a fifth connecting electrode bonded to the second connecting electrode; and a sixth connecting electrode bonded to the third connecting electrode, the first circuit includes: a first transistor and a second transistor including a first semiconductor layer; a trench; a first insulating layer; and a second insulating layer, wherein the first transistor is connected to the first word line via the first connecting electrode and the fourth connecting electrode, the second transistor is connected to the second word line via the second connecting electrode and the fifth connecting electrode, the trench is arranged in the first semiconductor layer between the first transistor and the second transistor, the first insulating layer is formed in the trench, the second circuit is connected to the bit line via the third connecting electrode and the sixth connecting electrode, and the second insulating layer is in contact with the first insulating layer at an end portion of the first insulating layer on a side further from the memory cell array.

The storage device according to an embodiment can reduce the size of the storage device. Alternatively, the storage device can realize high speed and low power consumption of an input/output circuit used in the storage device.

Hereinafter, a storage device according to the present embodiment will be described in detail with reference to the drawings. In the following description, elements having substantially the same functions and configurations are denoted by the same reference signs, and will be described redundantly only when necessary. Each of the embodiments described below exemplifies a device and a method for embodying a technical idea of this embodiment. The technical idea of the embodiment is not limited to the following materials, shapes, structures, arrangements, and the like of the constituent parts. Various modifications may be made to the technical idea of the embodiment in addition to the scope of the claims.

### 1. First Embodiment

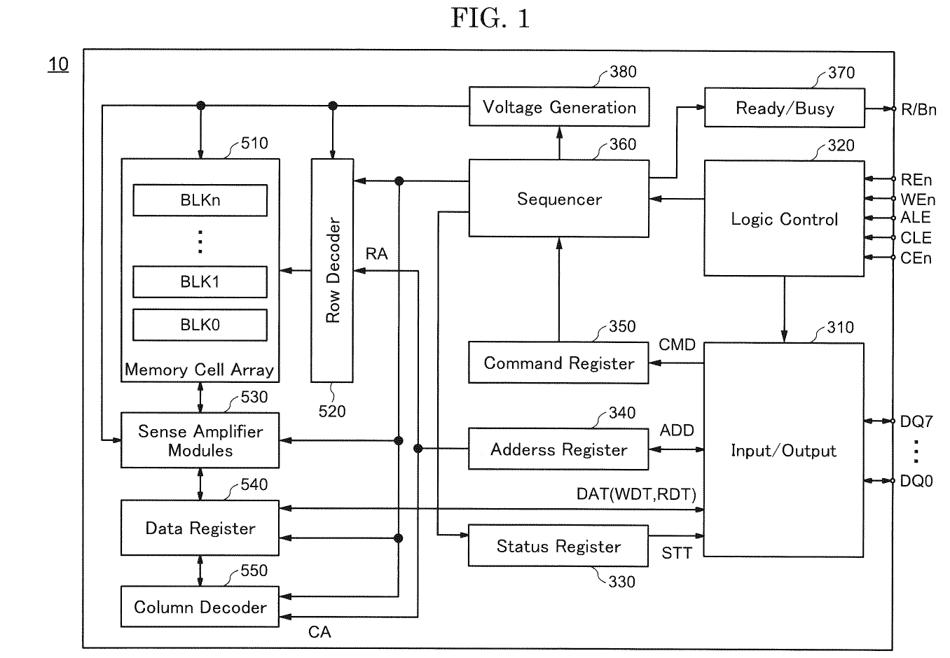

A storage device according to a first embodiment will be described with reference to FIG. 1 to FIG. 7.

### [1-1. Overall Configuration of Storage Device]

FIG. 1 is a block diagram of a storage device 10 according to an embodiment. As shown in FIG. 1, the storage device 10 includes an input/output circuit 310, a logic control circuit 320, a status register 330, an address register 340, a command register 350, a sequencer 360, a ready/busy circuit 370, a voltage generation circuit 380, a memory cell array 510, a row decoder 520, a sense amplifier module 530, a data register 540, and a column decoder 550.

The input/output circuit 310 controls the input/output of a signal DQ to/from an external device (not shown) such as a memory controller that controls the storage device 10. For example, the signal DQ is an 8-bit signal of DQ0 to DQ7. The input/output circuit 310 includes an input circuit and an output circuit (not shown).

The input circuit transmits data DAT such as a write data WDT received from the external device to the data register 540, transmits an address ADD to the address register 340, and transmits a command CMD to the command register 350.

The output circuit transmits status information STT received from the status register 330, the data DAT such as read data RDT received from the data register 540, and the address ADD received from the address register 340 to the external device.

The logic control circuit 320 receives, for example, a chip enable signal CEn, a command latch enable signal CLE, an address latch enable signal ALE, a write enable signal WEn, and a read enable signal REn from the external device. The logic control circuit 320 controls the input/output circuit 310 and the sequencer 360 in response to the received signal.

For example, the status register 330 temporarily holds the status information STT for a data write operation, a read operation, and an erase operation, and notifies the external device via the input/output circuit 310 whether the operation has been completed normally.

The address register 340 temporarily holds the address ADD received from the external device via the input/output circuit 310. The address register 340 transfers a row address RA to the row decoder 520, and transfers a column address CA to the column decoder 550.

The command register 350 temporarily stores the command CMD received from the external device via the input/output circuit 310 and transfers it to the sequencer 360.

The sequencer 360 controls the overall operation of the storage device 10. More specifically, for example, the sequencer 360 executes the write operation, the read operation, the erase operation, and the like by controlling the status register 330, the ready/busy circuit 370, the voltage generation circuit 380, the row decoder 520, the sense amplifier module 530, the data register 540, the column decoder 550, and the like in response to the command CMD transferred from the command register 350.

The ready/busy circuit 370 transmits a ready/busy signal R/Bn to the external device according to the operation status of the sequencer 360.

The voltage generation circuit 380 generates voltages necessary for the write operation, the read operation, and the erase operation under the control of the sequencer 360, and supplies the generated voltages to, for example, the memory cell array 510, the row decoder 520, the sense amplifier module 530, and the like. The row decoder 520 and the sense amplifier module 530 apply the voltage supplied from the voltage generation circuit 380 to the memory cells in the memory cell array 510.

The memory cell array 510 includes a plurality of blocks BLK (BLK0 to BLKn). n is an integer of 2 or more. The block BLK is a set of a plurality of memory cells associated with bit lines and word lines. For example, the block BLK is a data-erase unit. For example, the memory cell is a charge-storing transistor, and stores data in a non-volatile manner by the held charge. By including such a memory cell, the storage device 10 functions as, for example, a NAND-type non-volatile memory.

The row decoder 520 decodes the row address RA. The row decoder 520 selects one of the plurality of blocks BLK based on the result of the decoding. The row decoder 520 applies the voltages required for the write operation, the read operation, and the erase operation to the block BLK.

In the read operation, the sense amplifier module 530 senses (detects) the data read from the memory cell array 510. In the read operation, the sense amplifier module 530 transmits the read data RDT to the data register 540. In the write operation, the sense amplifier module 530 transmits the write data WDT to the memory cell array 510.

Although details will be described later, the data register 540 includes a plurality of latch circuits. The latch circuit holds the write data WDT and the read data RDT. For example, in the write operation, the data register 540 temporarily holds the write data WDT received from the input/output circuit 310 and transmits it to the sense amplifier module 530. In the read operation, the data register 540 temporarily holds the read data RDT received from the sense amplifier module 530 and transmits it to the input/output circuit 310.

The column decoder 550 decodes the column address CA during, for example, the write operation, the read operation, and the erase operation, and selects the latch circuit in the data register 540 according to the result of the decoding.

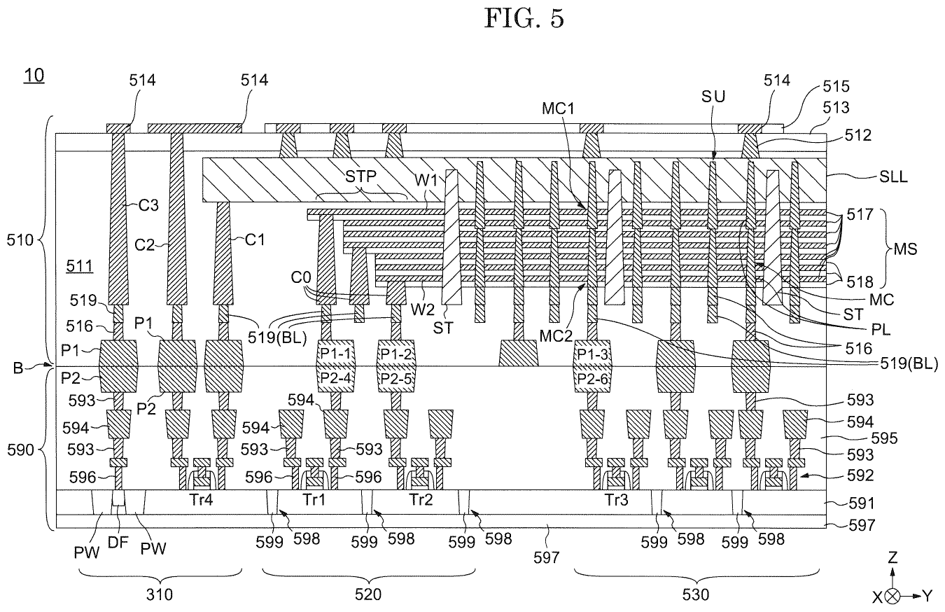

A group of circuits arranged around the memory cell array 510 may be referred to as a peripheral circuit 590 (see FIG. 5). The peripheral circuit 590 includes at least the input/output circuit 310, the row decoder 520, and the sense amplifier module 530. The status register 330, the address register 340, the command register 350, and the sequencer 360 may be included in the peripheral circuit 590. Further, the logic control circuit 320, the ready/busy circuit 370, and the voltage generation circuit 380 may be included in the peripheral circuit 590.

As described above, the storage device 10 includes the memory cell array 510 including the plurality of memory cells and the peripheral circuit 590 that drives the plurality of memory cells.

### [1-2. Configuration of Memory Cell Array]

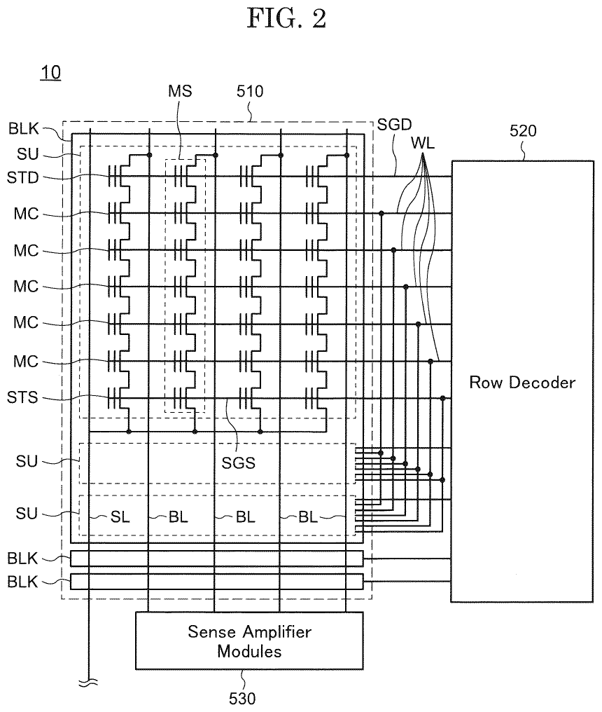

The circuit configuration of the memory cell array 510 will be described with reference to FIG. 2. FIG. 2 is a diagram for describing an equivalent circuit showing a configuration of the memory cell array of the storage device according to an embodiment.

The memory cell array 510 includes the plurality of blocks BLK as described above. Each of the plurality of blocks BLK includes a plurality of string units SU. Each of the plurality of string units SU includes a plurality of memory strings MS. One end of each of the plurality of memory strings MS is connected to the peripheral circuit 590 such as the sense amplifier module 530 via a bit line BL. The other end of each of the plurality of memory strings MS is connected to the peripheral circuit 590 such as the row decoder 520 via a common source line SL.

The memory string MS is arranged between the bit line BL and the source line SL. The memory string MS includes a drain select transistor STD, a plurality of memory cells MC, and a source select transistor STS connected in series between the bit line BL and the source line SL. Hereinafter, the drain select transistor STD and the source select transistor STS may be simply referred to as the select transistor (STD, STS).

For example, the memory cell MC is a field-effect transistor (FET) including a charge storage layer in a gate insulating layer. The threshold voltage of the memory cell MC varies depending on the amount of charges held in the charge storage layer. By arranging one or more threshold voltages, the memory cell MC can store one or more bits of data. Word lines WL are connected to gate terminals of the plurality of memory cells MC corresponding to one memory string MS, respectively. These word lines WL are commonly connected to the plurality of (or all) memory strings MS in one block BLK, respectively.

For example, the select transistor (STD, STS) is a field-effect transistor. Select gate lines (SGD, SGS) are connected to gate terminals of the select transistor (STD, STS), respectively. The select gate line SGD connected to the drain select transistor STD is arranged corresponding to the string unit SU, and is commonly connected to the plurality of (or all) memory strings MS in one string unit SU. The select gate line SGS connected to the source select transistor STS is commonly connected to the plurality (or all) of memory strings MS in one block BLK.

One end of each word line WL and the select gate lines (SGD, SGS) is connected to the peripheral circuit 590 such as the row decoder 520.

### [1-3. Configuration of Sense Amplifier Module]

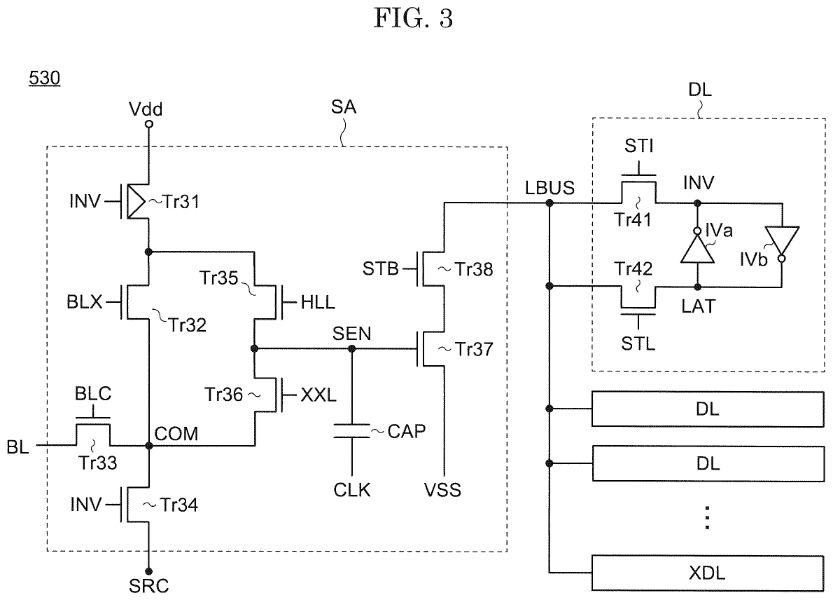

A circuit configuration of the sense amplifier module 530 will be described with reference to FIG. 3. FIG. 3 is a diagram for explaining a circuit configuration of a sense amplifier module of the storage device according to an embodiment. As shown in FIG. 3, the sense amplifier module 530 includes a sense amplifier circuit SA, a plurality of latch circuits DL, and a latch circuit XDL.

The sense amplifier SA is arranged for one or more bit lines BL. For example, in the read operation, the sense amplifier SA senses the data stored in the memory cell to be read which is data read in the bit line BL corresponding to the memory cell, and determines whether the read data is “0”or “1”.

The plurality of latch circuits DL and the latch circuit XDL are arranged corresponding to a plurality of sense amplifier circuits SA, respectively. That is, the plurality of latch circuits DL and the latch circuit XDL are arranged for each bit line BL. Therefore, the plurality of latch circuits DL is arranged for one sense amplifier circuit SA. The number of latch circuits DL is designed based on, for example, the bit line BL of data that one memory cell MC can hold. The plurality of latch circuits DL and the latch circuit XDL temporarily hold the data determined by the sense amplifier circuit SA with respect to the corresponding bit line BL.

FIG. 3 shows one sense amplifier circuit SA in the sense amplifier module 530 and the plurality of latch circuits DL and the latch circuit XDL arranged corresponding to the sense amplifier circuit SA. A plurality of control signals supplied to the sense amplifier SA and the like is controlled by the sequencer 360. FIG. 3 shows a typical latch circuit DL configuration, but it is possible to simplify the configuration of the latch circuit DL by utilizing the characteristics caused by the transistor structure of the present embodiment (details will be described later).

As shown in FIG. 3, the sense amplifier SA includes transistors Tr31 to Tr38 and a capacitor CAP. The transistor Tr31 is a P-channel MOS (Metal Oxide Semiconductor) transistor. The transistors Tr32 to Tr38 are an N-channel MOS transistors.

A CMOS transistor including the P-channel MOS transistor and the N-channel MOS transistor is a transistor to which a relatively low voltage is applied and may be referred to as a low voltage (LV: Low Voltage, VLV: Very Low Voltage) MOS transistor. On the other hand, a high-voltage CMOS transistor including a high-voltage P-channel MOS transistor and a high-voltage N-channel MOS transistor, which will be described later, is a transistor to which a relatively high voltage is applied, and may be referred to as a high voltage (HV: High Voltage) MOS transistor.

A first terminal of the transistor Tr31 is connected to a power line to which a power supply voltage Vdd is supplied, and a gate terminal of the transistor Tr31 is connected to a node INV. A first terminal of the transistor Tr32 is connected to a second terminal of the transistor Tr31, and a second terminal of the transistor Tr32 is connected to a node COM. A control signal BLX is input to a gate terminal of the transistor Tr32. A first terminal of the transistor Tr33 is connected to the node COM, and a second terminal of the transistor Tr33 is connected to the corresponding bit line BL via a high-voltage N-channel MOS transistor (not shown). A control signal BLC is input to a gate terminal of the transistor Tr33.

A first terminal of the transistor Tr34 is connected to the node COM, a second terminal of the transistor Tr34 is connected to a node SRC, and a gate terminal of the transistor Tr34 is connected to the node INV.

A first terminal of the transistor Tr35 is connected to the second terminal of the transistor Tr31, and a second terminal of the transistor Tr35 is connected to a node SEN. A control signal HLL is input to a gate terminal of the transistor Tr35. A first terminal of the transistor Tr36 is connected to the node SEN, and a second terminal of the transistor Tr36 is connected to the node COM. A control signal XXL is input to a gate terminal of the transistor Tr36.

A ground voltage VSS is supplied to a first terminal of the transistor Tr37. A gate terminal of the transistor Tr37 is connected to the node SEN. A first terminal of the transistor Tr38 is connected to a second terminal of the transistor Tr37, and a second terminal of the transistor Tr38 is connected to a bus LBUS. A control signal STB is input to a gate terminal of the transistor Tr38. A first terminal of the capacitor CAP is connected to the node SEN. A clock CLK is input to a second terminal of the capacitor CAP.

The latch circuit DL includes inverters IVa and IVb and transistors Tr41 and Tr42. As described above, the latch circuit DL is arranged in the data register 540. The transistors Tr41 and Tr42 are N-channel MOS transistors. Hereinafter, the transistors Tr41 and Tr42 included in the latch circuit DL may be simply referred to as a transistor Tr.

The inverter IVa has a configuration in which an input terminal is connected to a node LAT and an output terminal is connected to the node INV. The inverter IVb has a configuration in which an input terminal is connected to the node INV and an output terminal is connected to the node LAT.

The transistor Tr41 has a configuration in which a first terminal is connected to the node INV, a second terminal is connected to the bus LBUS, and a control signal STI is input to a gate terminal. The transistor Tr42 has a configuration in which a first terminal is connected to the node LAT, a second terminal is connected to the bus LBUS, and a control signal STL is input to a gate terminal.

For example, the latch circuit XDL has substantially the same configuration as the latch circuit DL, and is connected to the bus LBUS so as to be able to transmit and receive data to and from the sense amplifier circuit SA and the latch circuit DL. The latch circuit XDL is connected to the input/output circuit 310 described above, and is used for the input/output of data between the sense amplifier circuit SA and the input/output circuit 310.

The latch circuit XDL is also used for the caching operation of the storage device 10. That is, even when all the latch circuits DL corresponding to the sense amplifier circuit SA are in use, the storage device 10 can receive data from the outside if there is a usable latch circuit XDL.

Next, the operation of the sense amplifier SA having the above-described configuration will be briefly described. In the case where a data write operation is performed on the memory cell MC, the threshold of the memory cell MC is increased by injecting a charge into the charge storage layer of the memory cell MC. In this case, the node INV of the latch circuit DL is controlled to the “H” level (for example, data of “1” is stored). As a result, the transistor Tr34 whose gate terminal is connected to the node INV is turned on, and the voltage (for example, 0 V) supplied to the node SRC is supplied to the bit line BL. On the other hand, in the case where the threshold of the memory cell MC is not changed by not injecting the charge into the charge storage layer of the memory cell MC, the node INV of the latch circuit DL is controlled to the “L” level (for example, data of “0” is stored). As a result, the transistor Tr31 whose gate terminal is connected to the node INV is turned on, and a predetermined positive voltage (voltage supplied to the power supply voltage Vdd) is supplied to the bit line BL.

In the case where the read operation is performed, the node INV is controlled to the “L” level and the transistor Tr31 is turned on. Further, the bit line BL is precharged by the transistor Tr31 via the transistors Tr32 and Tr33. The transistor Tr35 is also turned on, and the node SEN is charged to a predetermined potential.

After that, the transistor Tr35 is turned off, and the control signal XXL is controlled to the “H” level, so that the transistor Tr36 is turned on. As a result, when the corresponding memory cell MC is in the on-state, the potential of the node SEN decreases, and the transistor Tr37 is turned off. On the other hand, when the corresponding memory cell MC is in the off-state, the potential of the node SEN is maintained at the “H” level, and the transistor Tr37 is turned on.

Subsequently, the transistor Tr38 is turned on by the control signal STB, and the potential corresponding to the on/off of the transistor Tr37 is read out to the bus LBUS and held in the latch circuit DL.

The circuit configurations of the sense amplifier circuit SA, the plurality of latch circuits DL, and the latch circuit XDL shown in FIG. 3 are examples, and may be configurations other than those described above. That is, the number and type of transistors Tr included in the sense amplifier circuit SA and the latch circuits DL and XDL may be different from the above configuration. For example, the sense amplifier circuit SA and the latch circuits DL and XDL may include the high-voltage P-channel MOS transistor, the high-voltage N-channel MOS transistor, or the like.

### [1-4. Circuit Configuration of Row Decoder]

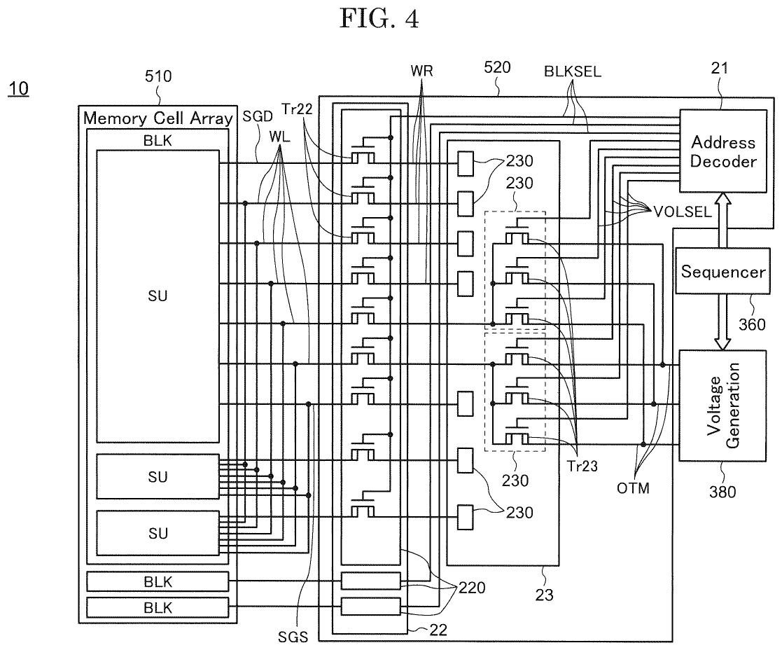

A circuit configuration of the row decoder 520 will be described with reference to FIG. 4. FIG. 4 is a diagram for explaining a circuit configuration of a row decoder of the storage device according to an embodiment. As shown in FIG. 4, the row decoder 520 includes an address decoder 21, a block select circuit 22, and a voltage select circuit 23.

The address decoder 21 includes a plurality of block select lines BLKSEL and a plurality of voltage select lines VOLSEL. For example, the address decoder 21 refers to address data of the address register 340 included in the peripheral circuit 590 in accordance with a control signal from the sequencer 360.

The address decoder 21 decodes the referenced address data, controls transistors Tr22 and Tr23 corresponding to the address data to be in the on-state, and controls the other transistors Tr22 and Tr23 to be in the off-state. The transistor Tr22 and the transistor Tr23 are transistors included in the block select circuit 22 and the voltage select circuit 23, respectively, which will be described later.

For example, the address decoder 21 controls the block select line BLKSEL and the voltage select line VOLSEL corresponding to the address data to the “H” level, and controls the other block select lines BLKSEL and the voltage select lines VOLSEL to the “L” level. In addition, the above example is an example in which an N-type transistor is used in the block select circuit 22 and the voltage select circuit 23. In the case where a P-type transistor is used in the block select circuit 22 and the voltage select circuit 23, the voltages applied to the respective wiring are reversed.

In the example of FIG. 4, in the address decoder 21, one block select line BLKSEL is arranged for one block BLK included in the memory cell array 510. However, this configuration can be changed as appropriate. For example, one block select line BLKSEL may be arranged for two or more blocks BLK.

The block select circuit 22 includes a plurality of block select units 220. The plurality of block select units 220 correspond to the block BLK of the memory cell array 510, respectively. The plurality of block select units 220 includes a plurality of transistors Tr22 corresponding to the word line WL and the select gate line (SGD, SGS), respectively. The transistor Tr22 is a transistor that selects the word line WL corresponding to the target memory cell MC.

The transistor Tr22 is a high-voltage N-channel MOS transistor and functions as a block-driving transistor. A drain terminal of the transistor Tr22 is electrically connected to the corresponding word line WL or the select gate line (SGD, SGS), respectively. A source terminal of the transistor Tr22 is electrically connected to a voltage output terminal OTM via a wiring WR and the voltage select circuit 23, respectively. The voltage output terminal OTM is electrically connected to the voltage generation circuit 380. A gate terminal of the transistor Tr22 is commonly connected to the corresponding block select line BLKSEL.

Although not shown, the block select circuit 22 includes a plurality of transistors connected between the select gate lines (SGD, SGS) and a ground voltage supply terminal. The plurality of transistors is the high-voltage CMOS transistor. The plurality of transistors conduct the select gate lines (SGD, SGS) included in the unselected block BLK in the memory cell array 510 to the ground voltage supply terminal. The plurality of word lines WL included in the unselected block BLK is floating.

The voltage select circuit 23 includes a plurality of voltage select units 230 corresponding to the word line WL and the select gate line (SGD, SGS). Each of the plurality of voltage select units 230 includes a plurality of transistors Tr23.

The transistor Tr23 is a high-voltage N-channel MOS transistor and functions as a voltage select transistor. A drain terminal of the transistor Tr23 is electrically connected to the corresponding word line WL or the select gate line (SGD, SGS) via the wiring WR and the block select circuit 22, respectively. A source terminal of the transistor Tr23 is electrically connected to the corresponding voltage output terminal OTM, respectively. A gate terminal of the transistor Tr23 is connected to the corresponding voltage select line VOLSEL, respectively.

As described above, the row decoder 520 included in the peripheral circuit 590 includes the plurality of transistors Tr22 and Tr23 and the like. However, the circuit configuration of the row decoder 520 shown in FIG. 4 is an example, and the number and type transistors Tr22 and Tr23 and the like included in the row decoder 520 are not limited to the above example.

### [1-5. Cross-Sectional Structure of Storage Device 10]

A cross-sectional structure of the storage device 10 will be described with reference to FIG. 5. FIG. 5 is a cross-sectional view showing an outline of a storage device according to an embodiment. As shown in FIG. 5, a main surface of a semiconductor layer 591 of the peripheral circuit 590 extends in a direction X and a direction Y. A direction orthogonal to each of the direction X and the direction Y is a direction Z. In the following description, the direction Z may be referred to as “upper” or “above,” and the reverse may be referred to as “lower” or “below.”

As shown in FIG. 5, the memory cell array 510 and the peripheral circuit 590 are bonded to each other on a bonding surface B. A connection electrode P1 is arranged on the bonding surface B of the memory cell array 510. A connection electrode P2 is arranged on the bonding surface B of the peripheral circuit 590. The circuit arranged in the memory cell array 510 is electrically connected to the circuit arranged in the peripheral circuit 590 via the connection electrodes P1 and P2.

In the following description, when the connection electrode P1 is described individually, it will be referred to as connection electrodes P1-1, P1-2, and P1-3. If they do not need to be distinguished, they are referred to as the connection electrode P1 as described above. Similarly, when the connection electrode P2 is described individually, it will be referred to as connection electrodes P2-4, P2-5, and P2-6. If they do not need to be distinguished, they are referred to as the connection electrode P2 as described above.

The connection electrode P1-1 may be referred to as a “first connection electrode”. The connection electrode P1-2 may be referred to as a “second connection electrode”. The connection electrode P1-3 may be referred to as a “third connection electrode”. The connection electrode P2-4 may be referred to as a “fourth connection electrode”. The connection electrode P2-5 may be referred to as a “fifth connection electrode”. The connection electrode P2-6 may be referred to as “sixth connection electrode”. The connection electrode P1-1 (first connection electrode) is bonded to the connection electrode P2-4 (fourth connection electrode). The connection electrode P1-2 (second connection electrode) is bonded to the connection electrode P2-5 (fifth connection electrode). The connection electrode P1-3 (third connection electrode) is bonded to the connection electrode P2-6 (sixth connection electrode).

The peripheral circuit 590 includes the semiconductor layer 591, a processing circuit 592, a via 593, a wiring 594, an insulating layer 595, a contact 596, an insulating layer 597, and the connection electrode P2.

For example, a silicon layer is used as the semiconductor layer 591. The semiconductor layer 591 is thinner than a silicon wafer commonly used as a substrate. A thickness of the semiconductor layer 591 is 10 nm or more and 1 μm or less. The thickness of the semiconductor layer 591 may be 50 nm or more and 1 μm or less, 100 nm or more and 500 nm or less, or 100 nm or more and 300 nm or less. For example, the thickness of the semiconductor layer 591 may be the same as the thickness of an active layer in the commonly used SOI (Silicon On Insulator) substrate.

A trench 598 is arranged in the semiconductor layer 591. An insulating layer 599 is arranged inside the trench 598. The lower surface of the semiconductor layer 591 is covered with the insulating layer 597. Since the trench 598 reaches the insulating layer 597, the lower surface of the insulating layer 599 is in contact with the insulating layer 597. For example, silicon oxide or silicon nitride is used as the insulating layers 597 and 599. In the present embodiment, since the trench 598 is formed from above, the side wall of the trench 598 is tapered with the slope facing upward. In other words, the shape of the trench 598 in a cross-sectional view is such that the width of the trench 598 in the direction parallel to the bonding surface B increases as the position of the trench 598 approaches the memory cell array 510. In other words, the distance between the opposing side walls in the trench 598 gradually increases from the bottom to the top.

The insulating layer 599 may be referred to as a “first insulating layer.” The insulating layer 597 may be referred to as a “second insulating layer.” The insulating layer 597 (second insulating layer) is in contact with the insulating layer 599 (first insulating layer) at the lower end (end portion on the side farther from the memory cell array 510) of the insulating layer 599 (first insulating layer). Similarly, the insulating layer 597 (second insulating layer) is in contact with the semiconductor layer 591 (first semiconductor layer) on the lower surface of the semiconductor layer 591 (the surface on the side farther from the memory cell array 510).

The processing circuit 592 includes the transistor Tr having the semiconductor layer 591 as a channel. For example, the processing circuit 592 includes the input/output circuit 310, the row decoder 520, and the sense amplifier module 530. The transistor Tr included in the row decoder 520 may be referred to as a first transistor Tr1 and a second transistor Tr2. The transistor Tr included in the sense amplifier module 530 may be referred to as a third transistor Tr3. The transistor Tr included in the input/output circuit 310 may be referred to as a fourth transistor Tr4. If these transistors do not need to be distinguished in particular, they are simply referred to as the transistor Tr. The processing circuit 592 includes a capacity element and a resistance element in addition to the transistor.

The semiconductor layer 591 corresponding to the first transistor Tr1 and the second transistor Tr2 may be referred to as a “first semiconductor layer”. The semiconductor layer 591 corresponding to the third transistor Tr3 may be referred to as a “second semiconductor layer”. The semiconductor layer 591 corresponding to the fourth transistor Tr4 may be referred to as a “third semiconductor layer”. The lower surfaces of the second semiconductor layer and the third semiconductor layer (the surfaces on the side farther from the memory cell array 510) may be referred to as being covered with the insulating layer 597 (second insulating layer). In the present embodiment, the thickness of the first semiconductor layer, the thickness of the second semiconductor layer, and the thickness of the third semiconductor layer are the same.

The row decoder 520 may be referred to as a “first circuit”. The sense amplifier module 530 may be referred to as a “second circuit.” The input/output circuit 310 may be referred to as a “third circuit”. In this case, the row decoder 520 (first circuit) may include the first transistor Tr1 and the second transistor Tr2. The sense amplifier module 530 (second circuit) may include the third transistor Tr3. The sense amplifier module 530 (second circuit) may include the fourth transistor Tr4.

The row decoder 520 (first circuit), the sense amplifier module 530 (second circuit), and the input/output circuit 310 (third circuit) are controlled by the logic control circuit 320 and the sequencer 360. The logic control circuit 320 and the sequencer 360 may also be referred to as a “control circuit”.

The row decoder 520 (first circuit), the sense amplifier module 530 (second circuit), and the input/output circuit 310 (third circuit) include the insulating layer 597, the trench 598, and the insulating layer 599. The trench 598 is arranged between adjacent transistors. Specifically, the trench 598 is arranged between the first transistor Tr1 and the second transistor Tr2. As described above, the input/output circuit 310 (third circuit) is connected to the row decoder 520 (first circuit) and the sense amplifier module 530 (second circuit), and transmits and receives signals to and from an external device.

The contact 596 is an electrode arranged in an opening of the insulating layer 595 and extending in the direction Z. The contact 596 is in contact with the semiconductor layer 591, and is electrically connected to the source terminal and the drain terminal of the transistor Tr.

The via 593 is a wiring arranged in the opening of the insulating layer 595 and extending in the direction Z. The via 593 electrically connects the contact 596 and the wiring 594. In FIG. 5, the wiring 594 is shown only in one layer, but the wiring 594 is arranged in a plurality of layers in the direction Z via the insulating layer 595, and the wiring 594 adjacent in the direction Z is connected by the via 593. Similarly, the wiring 594 and the connection electrode P2 adjacent in the direction Z are connected by the via 593.

An N⁺ diffusion region DF sandwiched on both sides by a P-well PW is arranged in the end portion of the peripheral circuit 590. The N⁺ diffusion region DF is connected to the connection electrode P1 of the memory cell array 510 via the via 593, the wiring 594, the contact 596, and the connection electrode P2 arranged in the semiconductor layer 591.

The memory cell array 510 includes the memory string MS, a slit ST, a source layer SLL, insulating layers 511, 513, 515, and 518, a contact C1, vias C2, C3, 512, and 516, and wirings 514 and 519.

The memory string MS includes a pillar PL, a plurality of wirings 517, and a plurality of insulating layers 518. The pillar PL extends in the direction Z. A plurality of pillars PL is arranged in the direction Z. In the example of FIG. 5, two pillars PL are stacked in the direction Z. A configuration including the stacked pillar PL and the plurality of memory strings MS is referred to as a string unit SU.

The pillar PL includes a core layer, a semiconductor layer, insulating layers, and the charge storage layer. The core layer is the core of the pillar PL and is an insulator. The semiconductor layer is arranged around the core layer, the insulating layer is arranged around the semiconductor layer, the charge storage layer is arranged around the insulating layer, the insulating layer is arranged around the charge storage layer, and the wiring 517 is arranged around the insulating layer. The wiring 517 and the insulating layer 518 are alternately stacked along the direction Z. As described above, the plurality of wirings 517 is arranged so as to surround the insulating layer outside the pillar PL. A portion where one of the plurality of wirings 517 and the pillar PL face each other is the memory cell MC. That is, the wiring 517 functions as a gate electrode of the memory cell MC.

The plurality of wirings 517 extend in the direction Y. The plurality of wirings 517 function as the word line WL and the select gate line. A stepped portion STP is arranged on the end portion of the plurality of wirings 517 in the direction Y. Due to the stepped shape in the stepped portion STP, each of the plurality of wirings 517 is sequentially exposed from the wiring 517 below it and is connected to the wiring 519 via a via C0.

The semiconductor layer of the pillar PL is connected to the via 516 and the source layer SLL. The via 516 is connected to the wiring 519, which functions as the bit line BL. The bit line BL extends in the direction X. The bit line BL is connected to the connection electrode P1 via the via 516.

The via 512, the insulating layer 513, the wiring 514, and the insulating layer 515 are arranged above the source layer SLL. The wiring 514 arranged at a position corresponding to the N⁺ diffusion region DF of the peripheral circuit 590 is connected to the connection electrode P2 of the peripheral circuit 590 via the via C3, the wiring 519, the via 516, and the connection electrode P1. The semiconductor layer 591 and the source layer SLL are electrically connected via the via C1, the wiring 519, the via 516, and the connection electrode P1.

Among the plurality of wirings 517, in the stepped portion STP, the wiring 517 connected to the connection electrode P1-1 via the via C0 may be referred to as a “first word line W1”. Similarly, the wiring 517 connected to the connection electrode P1-2 via the via C0 may be referred to as a “second word line W2”. The memory cell MC in which the first word line W1 is the gate electrode may be referred to as a “first memory cell MC1”. The memory cell MC in which the second word line W2 is the gate electrode may be referred to as a “second memory cell MC2”.

In this case, the first memory cell and the second memory cell are connected to the common bit line BL. The first transistor Tr1 is connected to the first word line W1 via the first the connection electrode P1-1 (first connection electrode) and the connection electrode P2-4 (fourth connection electrode). The second transistor Tr2 is connected to the connection electrode P1-2 (second connection electrode) and the connection electrode P2-5 (fifth connection electrode) via the second word line W2. The third transistor Tr3 is connected to the bit line BL via the connection electrode P1-3 (third connection electrode) and the connection electrode P2-6 (sixth connection electrode).

Since the third transistor Tr3 is the transistor Tr included in the sense amplifier module 530 (second circuit), it can be said that the second circuit is connected to the bit line BL. For example, the third transistor Tr3 may be the transistor Tr used in any one of the plurality of latch circuits DL and the latch circuit XDL.

### [1-6. Cross-sectional Structure and Partial Planar Shape of Transistor Tr]

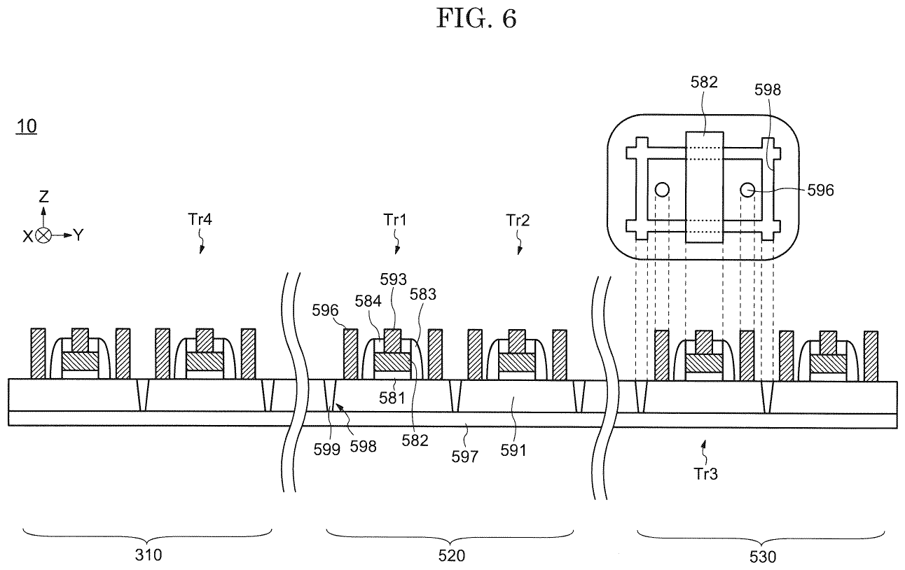

A cross-sectional structure of the transistor Tr will be described with reference to FIG. 6. As shown in FIG. 6, the transistor Tr includes the semiconductor layer 591, a gate insulating layer 581, a gate electrode 582, a sidewall 583, an insulating layer 584, the via 593, and the contact 596. The insulating layer 597 is arranged below the semiconductor layer 591. The trench 598 is arranged between the adjacent transistors Tr. The insulating layer 599 is arranged inside the trench 598. In FIG. 6, the first transistor Tr1 to the fourth transistor Tr4 are shown, and the plan view thereof is shown only above the third transistor Tr3.

The gate electrode 582 is arranged at a position facing the semiconductor layer 591 that functions as a channel region of the transistor Tr. The gate insulating layer 581 is arranged between the semiconductor layer 591 and the gate electrode 582. The insulating layer 584 is arranged on the gate electrode 582, and the via 593 is arranged in an opening arranged in the insulating layer 584. The via 593 is connected to the gate electrode 582. When a voltage is applied to the gate electrode 582 via the via 593, carriers constituting the current path are generated in the semiconductor layer 591 facing the gate electrode 582. The sidewall 583 is arranged so as to cover the side wall of the gate electrode 582. The contact 596 functions as the source electrode and the drain electrode of the transistor Tr.

As described above, the thickness of the semiconductor layer 591 is 10 nm or more and 1 μm or less, and is approximately equal to the thickness of the active layer in the typical SOI substrate. That is, the transistor Tr (the first transistor Tr1 to the fourth transistor Tr4) in the present embodiment has the same function as the transistor formed on the SOI substrate. In the transistor Tr, the semiconductor layer 591 is floating because the insulating layer 597 is arranged on the lower surface of the semiconductor layer 591 and the trench 598 is arranged between the semiconductor layers 591 adjacent in the direction X and the direction Y. Therefore, charges are accumulated in the semiconductor layer 591. Since the threshold value of the transistor Tr varies depending on the amount of charges accumulated in the semiconductor layer 591, the transistor Tr in the present embodiment has a function as a switching element and a function as a memory element. In other words, the transistor Tr functions as a floating body cell.

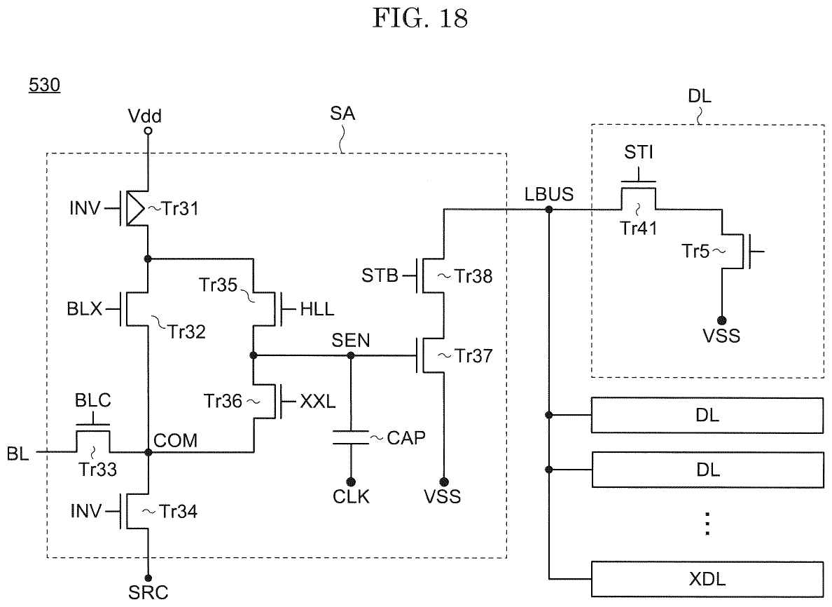

Since the transistor Tr has the above-described function, the function of the latch circuits DL and XDL shown in FIG. 3 can be realized by a simplified circuit configuration (see FIG. 18). The latch circuits DL and XDL shown in FIG. 3 are composed of two transistors Tr41 and Tr42 and two inverters IVa and IVb. However, since the transistor Tr5 shown in FIG. 18 has a function as a switching element and a function as a memory element, the two transistors and the two inverters shown in FIG. 3 can be replaced with two transistors Tr5 and Tr41 as shown in FIG. 18. As shown in FIG. 18, a first terminal of the transistor Tr5 is connected to a first terminal of the transistor Tr41. A second terminal of the transistor Tr5 is connected to the ground voltage VSS (a source line of the floating body cell). A gate terminal of the transistor Tr5 is connected to a word line of the floating body cell. For example, the transistor Tr5 is a transistor included in the sense amplifier module 530 as shown in FIG. 6, and functions as a floating body cell as in the transistor Tr3. Therefore, the transistors Tr5 and Tr41 functions as the latch circuit DL. In addition, the transistor Tr41 may be a transistor that functions as a floating body cell, and may not be a transistor that functions as a floating body cell.

In the transistor used in the conventional storage device, there is a problem that the operation speed of the transistor decreases due to the junction capacitance at the junction between the diffusion layer and the well. However, the transistor Tr in the present embodiment has the same function as the transistor formed on the SOI substrate. Therefore, in the transistor Tr according to the present embodiment, the effect of the junction capacitance between the diffusion layer and the well is suppressed, so that the transistor Tr can be operated at high speed and with low power consumption. Further, in the transistor Tr according to the present embodiment, the junction leakage between the diffusion layer and the well does not occur, so that the power consumption of the transistor Tr can be reduced mainly in the standby state.

As shown in FIG. 6, the width of the trench 598 in the direction Y arranged between the transistors Tr arranged in the direction Y is 200 nm or less. The width of the trench 598 in the direction Y may be 150 nm or less and may be 100 nm or less. The depth of the trench 598 in the direction Z is the same as the thickness of the semiconductor layer 591. For example, in the case where the thickness of the semiconductor layer 591 is 300 nm or less, the depth of the trench 598 is also 300 nm or less.

As shown in a plan view above the third transistor Tr3 in FIG. 6, the trench 598 is arranged so as to surround the transistor Tr. That is, the semiconductor layer 591 of the transistor Tr adjacent in the direction X and the direction Y is insulated by the insulating layer 599 arranged in the trench 598 and the insulating layer 597 arranged on the lower surface of the semiconductor layer 591. Therefore, the width of the trench 598 in the present embodiment can be made smaller than the width of the conventional trench.

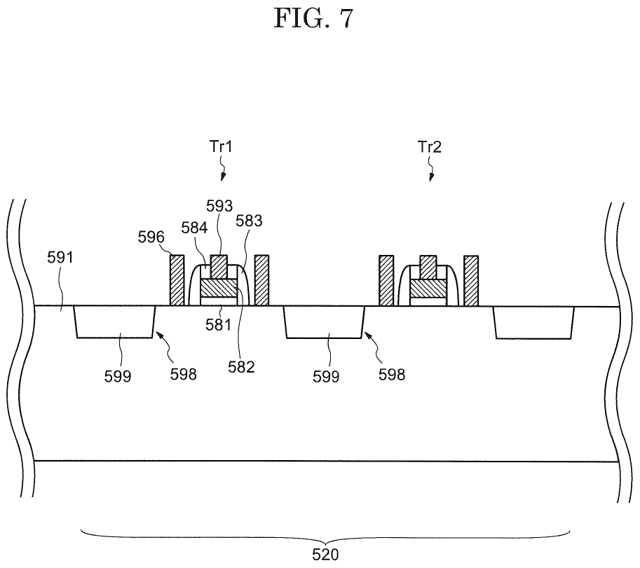

For reference, FIG. 7 shows a cross-sectional view of the storage device according to the comparative embodiment. In the conventional storage device, since the transistor is formed on the silicon wafer, the semiconductor layer 591 of the adjacent transistors is contiguous below the trench 598. Therefore, for example, in the row decoder 520 that supplies a voltage to the word line, since a voltage of 20 V or more is applied, in order to electrically isolate the semiconductor layer 591 of the adjacent transistors, the width of the trench 598 needs to be 600 nm or more. Even in a circuit such as the input/output circuit 310 or the sense amplifier module 530 in which the voltage applied to the circuit is 5 V or less or 2 V or less, in order to electrically isolate the semiconductor layer 591 of the adjacent transistors, the width of the trench 598 is 200 nm or more.

For example, in the case where the storage device 10 according to the present embodiment is a flash memory, a voltage of 20 V or more and 30 V or less is applied to the first word line W1 and the second word line W2 in order for the control circuit to drive the memory cell MC. In the conventional storage device, in order to withstand the high voltage supplied at the time of driving, the width of the trench 598 needs to be 600 nm or more. As a result, there is a limit to the reduction of the circuit.

On the other hand, in the storage device 10 according to the present embodiment, as shown in FIG. 6, the semiconductor layer 591 of the transistor Tr adjacent in the direction Y is separated by the trench 598 (the insulating layer 599) arranged therebetween and the insulating layer 597 arranged on the lower surface of the semiconductor layer 591. Therefore, in the storage device 10, as described above, the width of the trench 598 in the direction X and the direction Y can be made smaller than in the conventional storage device. As a result, for example, the circuit scales of the input/output circuit 310, the row decoder 520, the sense amplifier module 530, and the like can be reduced. In particular, in the row decoder 520 in which the transistor Tr needs to be arranged for each word line, by reducing the width of the trench 598, it is possible to greatly reduce the circuit scale.

### [1-7. Method for Manufacturing Storage Device 10]

A method for manufacturing the storage device 10 according to the present embodiment will be described. The transistor Tr, the trench 598, and the like on the semiconductor layer 591 (for example, a silicon wafer) thicker than the depth of the trench 598 similar to FIG. 7 are formed, and the insulating layer 599 inside the trench 598 are formed in the method for manufacturing the storage device 10. Thereafter, the semiconductor layer 591 is thinned from the lower surface side to obtain the storage device 10. Specifically, the transistor Tr or the like is formed on the silicon wafer, the trench 598 is formed near the upper surface of the silicon wafer between the adjacent transistors Tr, and the semiconductor layer 591 is thinned from the lower surface, thereby forming the storage device 10 shown in FIG. 6. The insulating layer 599 may be formed after the transistor Tr is formed, or may be formed during the process of forming the transistor Tr.

As described above, since the trench 598 is formed before thinning the semiconductor layer 591 (silicon wafer), the side wall of the trench 598 is tapered with the slope facing upward. In other words, the distance between the opposing side walls in the trench 598 gradually increases from the bottom to the top.

As described above, according to the storage device 10 of the present embodiment, since the width of the trench 598 can be reduced, the circuit scale can be reduced. Furthermore, in the transistor Tr in the storage device 10 according to the present embodiment, since there is no junction between the diffusion layer and the well, it is possible to realize high speed and low power consumption of the transistor Tr.

### 2. Second Embodiment

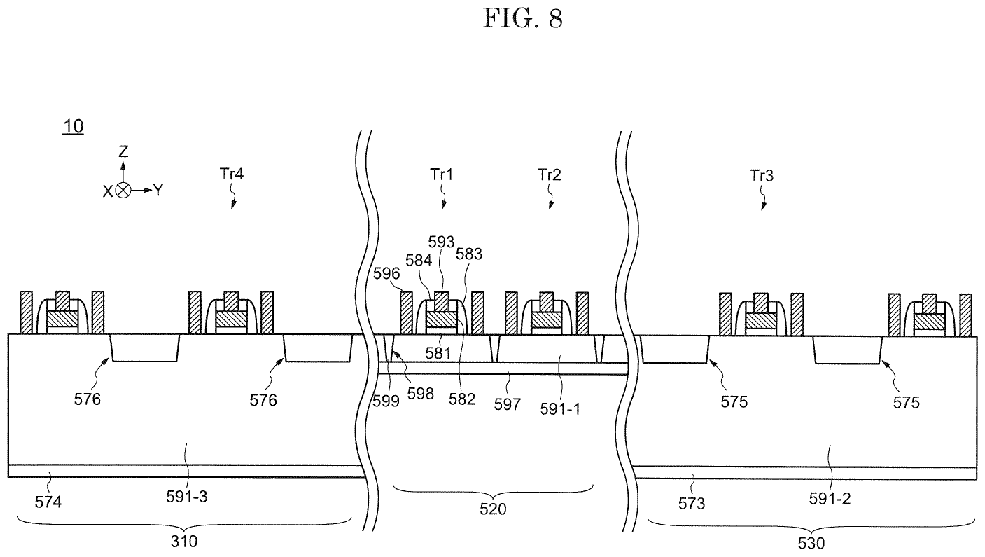

A storage device according to a second embodiment will be described with reference to FIG. 8. FIG. 8 is a cross-sectional view showing an outline of a storage device according to an embodiment. The storage device 10 shown in FIG. 8 is similar to the storage device 10 shown in FIG. 6, but is different from the storage device 10 shown in FIG. 6 in that semiconductor layers 591-2 and 591-3 in the input/output circuit 310 and the sense amplifier module 530 are thicker than a semiconductor layer 591-1 in the row decoder 520.

### [2-1. Cross-sectional Structure of Transistor Tr]

In FIG. 8, since the configuration of the row decoder 520 is the same as the configuration of the row decoder 520 shown in FIG. 6, the description will be omitted. However, in FIG. 8, the semiconductor layer of the row decoder 520 is described as the semiconductor layer 591-1.

The semiconductor layer of the transistor Tr3 arranged in the sense amplifier module 530 is the semiconductor layer 591-2. An insulating layer 573 is arranged on the lower surface of the semiconductor layer 591-2. A trench 575 is arranged near the upper surface of the semiconductor layer 591-2. The semiconductor layer of the transistor Tr4 arranged in the input/output circuit 310 is the semiconductor layer 591-3. An insulating layer 574 is arranged on the lower surface of the semiconductor layer 591-3. A trench 576 is arranged near the upper surface of the semiconductor layer 591-3.

The thickness of the semiconductor layer 591-2 and the thickness of the semiconductor layer 591-3 are both greater than the thickness of the semiconductor layer 591-1. The insulating layers 573 and 574 are made of the same material and have the same thickness as the insulating layer 597. The insulating layers 573, 574, and 597 are formed in the same process. In the direction Y, the widths of the trenches 575 and 576 are larger than the width of the trench 598. The thickness relationship of each semiconductor layer is not limited to the relationship described above. At least a part of the thickness of the semiconductor layer 591-1, the thickness of the semiconductor layer 591-2, and the thickness of the semiconductor layer 591-3 may be smaller than the thickness of other semiconductor layers. In addition, with respect to the configuration of the first embodiment, it can be said that the thickness of the semiconductor layer 591-1, the thickness of the semiconductor layer 591-2, and the thickness of the semiconductor layer 591-3 are the same.

The insulating layer 573 may be referred to as a “third insulating layer.” The semiconductor layer 591-2 may be referred to as a “second semiconductor layer.” In this case, it can be said that the sense amplifier module 530 (second circuit) includes the third transistor Tr3 and the insulating layer 573 (third insulating layer). The semiconductor layer 591-2 (second semiconductor layer) can be said to function as a channel of the third transistor Tr3. The lower surface (the surface on the side farther from the memory cell array 510) of the semiconductor layer 591-2 (second semiconductor layer) can be said to be covered with the insulating layer 573 (third insulating layer). Referring to FIG. 5 and FIG. 8, it can be said that the third transistor Tr3 is connected via the connection electrode P1-3 (third connection electrode) and the connection electrode P2-6 (sixth connection electrode) to the bit line BL.

The insulating layer 574 may be referred to as a “fourth insulating layer.” The semiconductor layer 591-3 may be referred to as a “third semiconductor layer.” In this case, it can be said that the input/output circuit 310 (third circuit) includes the fourth transistor Tr4 and the insulating layer 574 (fourth insulating layer). The semiconductor layer 591-3 (third semiconductor layer) can be said to function as a channel of the fourth transistor Tr4. It can be said that the lower surface (the surface on the side farther from the memory cell array 510) of the semiconductor layer 591-3 (third semiconductor layer) is covered with the insulating layer 574 (fourth insulating layer).

### [2-2. Method for Manufacturing Storage Device 10]

A method for manufacturing the storage device 10 according to the present embodiment will be described. Similar to the storage device 10 according to the first embodiment, the storage device 10 according to the present embodiment is formed by thinning the semiconductor layer 591 from the lower surface. However, when thinning the semiconductor layer 591, in order to expose the lower surface of the semiconductor layer 591-1 in a region where the row decoder 520 is formed, a mask such as a resist is formed on the lower surfaces of the semiconductor layers 591-2 and 591-3 in a region where the input/output circuit 310 and the sense amplifier module 530 are formed. The semiconductor layer 591-1 in the region where the row decoder 520 is formed can be selectively thinned by thinning in this state.

In the present embodiment, a configuration in which the semiconductor layer 591-1 corresponding to the row decoder 520 is thinned has been exemplified, but the configuration is not limited to this configuration. For example, the semiconductor layer 591 in a region where at least one of the input/output circuit 310, the row decoder 520, and the sense amplifier module 530 is formed may be selectively thinned. That is, the semiconductor layer 591 corresponding to the input/output circuit 310 may be thinned, the semiconductor layer 591 corresponding to the sense amplifier module 530 may be thinned, and the semiconductor layer 591 corresponding to two or more of the input/output circuit 310, the row decoder 520, and the sense amplifier module 530 may be thinned.

As described above, according to the storage device 10 of the present embodiment, the same effects as those of the storage device 10 of the first embodiment can be obtained. Further, the thickness of the semiconductor layer 591 can be adjusted as needed.

### 3. Third Embodiment

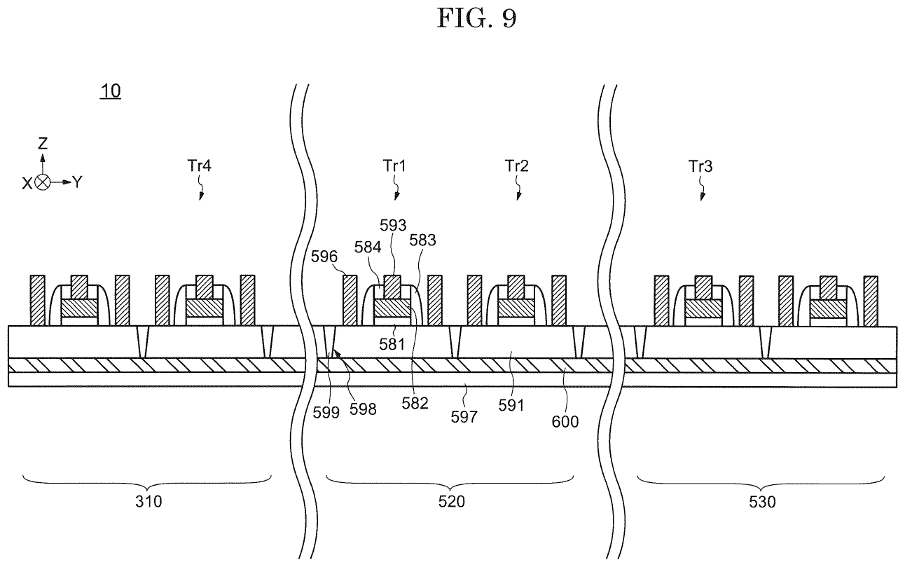

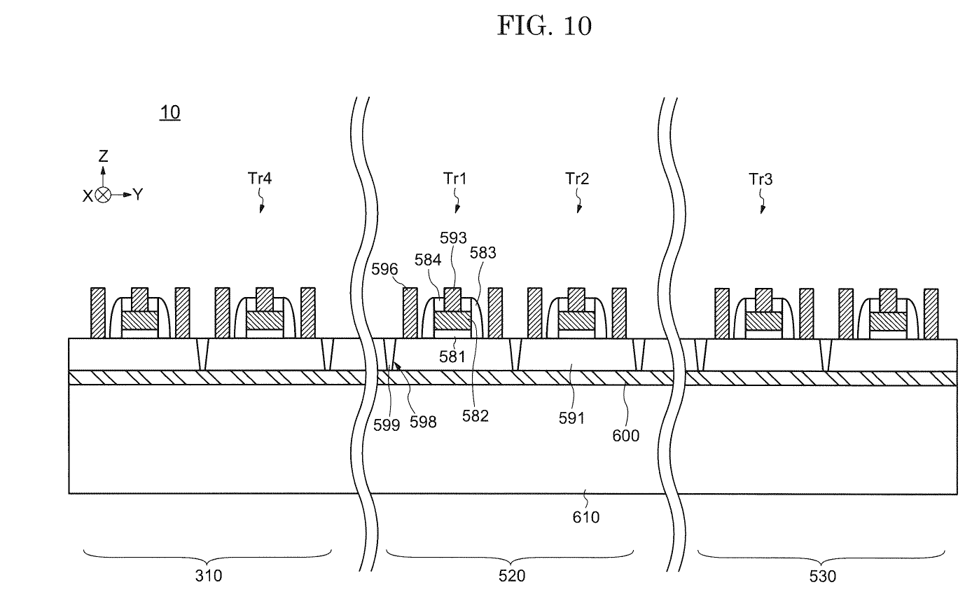

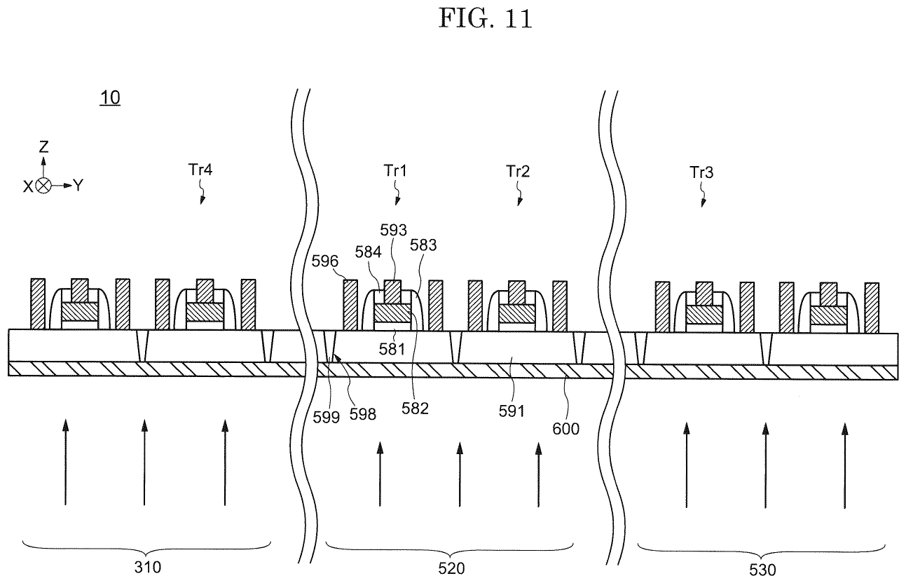

A storage device according to a third embodiment will be described with reference to FIG. 9 to FIG. 11. FIG. 9 is a cross-sectional view showing an outline of a storage device according to an embodiment. FIG. 10 and FIG. 11 are cross-sectional views illustrating a method for manufacturing a storage device according to an embodiment. The storage device 10 shown in FIG. 9 is similar to the storage device 10 shown in FIG. 6, but is different from the storage device 10 shown in FIG. 6 in that an etching stopper layer 600 is arranged between the semiconductor layer 591 and the insulating layer 597.

### [3-1. Cross-section of Transistor Tr]

In FIG. 9, the description of the same configuration as in FIG. 6 will be omitted, and the differences from FIG. 6 will be mainly described. As shown in FIG. 9, the lower surface of the semiconductor layer 591 is covered with the etching stopper layer 600. The trench 598 is arranged so as to reach the etching stopper layer 600. That is, the lower surface of the insulating layer 599 arranged inside the trench 598 is in contact with the etching stopper layer 600.

A material having a function as a stopper for a process of thinning the semiconductor layer 591 is used as the etching stopper layer 600. For example, in the case where the semiconductor layer 591 is formed by thinning the silicon wafer by CMP (Chemical Mechanical Polishing) and then further thinned by wet etching, the etching rate of the semiconductor layer 591 may be sufficiently large with respect to the etching rate of the etching stopper layer 600 with respect to the etching rate for the etchant used in the wet etching.

For example, a silicon germanium layer is used as the etching stopper layer 600. For example, the thickness of the silicon germanium layers is 10 nm or more and 50 nm or less. In the case where a silicon layer is used as the semiconductor layer 591 and a silicon germanium layer is used as the etching stopper layer 600, the semiconductor layer 591 and the etching stopper layer 600 may be collectively referred to as a “semiconductor layer”. This “semiconductor layer” can also be said to be composed of a plurality of semiconductor layers different from each other. Since the etching stopper layer 600 also functions as a stopper when the trench 598 is formed, the bottom of the trench 598 is present in the etching stopper layer 600. A silicon oxide layer may be used as the etching stopper layer 600.

### [3-2. Method for Manufacturing Storage Device 10]

A method for manufacturing the storage device 10 according to the present embodiment will be described with reference to FIG. 10 and FIG. 11. As shown in FIG. 10, a substrate in which the etching stopper layer 600 and the semiconductor layer 591 are formed on a silicon wafer 610 is prepared. The transistor Tr is formed on the substrate in the same manner as in the first embodiment, the trench 598 is formed with respect to the semiconductor layer 591 from the above, and the insulating layer 599 is formed inside the trench 598.

Subsequently, as shown in FIG. 11, the silicon wafer 610 is thinned from the lower surface side thereof. As described above, the thinning process includes at least a two-step process. The first step is mechanical thinning. The following second step is chemical thinning. For this chemical processing method, the etching rate of the silicon wafer 610 is sufficiently greater than the etching rate of the etching stopper layer 600. The CMP is used for the mechanical thinning as described above. The wet etching is used for the chemical processing as described above. However, a method other than the above may be used as the mechanical processing and the chemical processing.

As described above, according to the storage device 10 of the present embodiment, the same effects as those of the storage device 10 of the first embodiment can be obtained. In addition, the process margin for thinning the semiconductor layer 591 can be increased by the etching stopper layer 600.

### 4. Fourth Embodiment

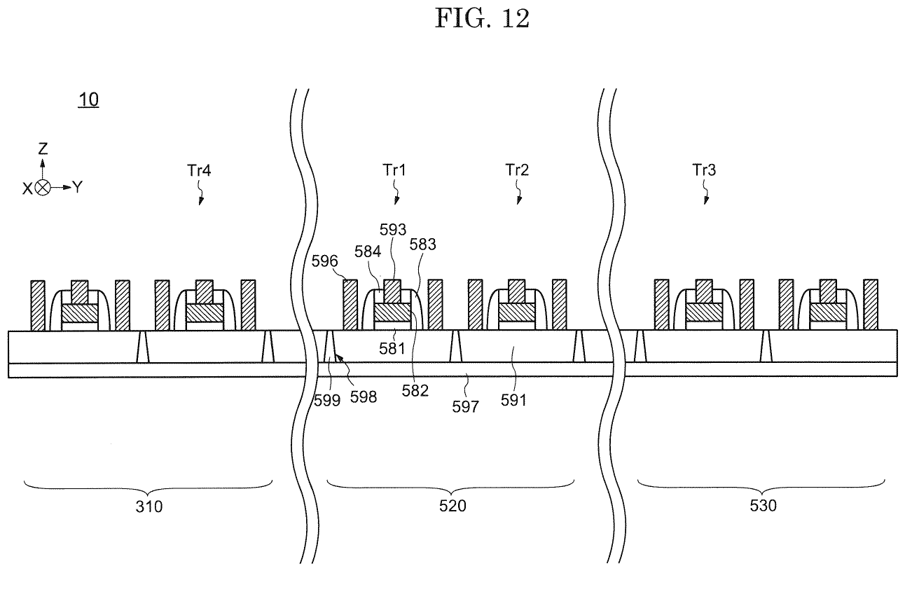

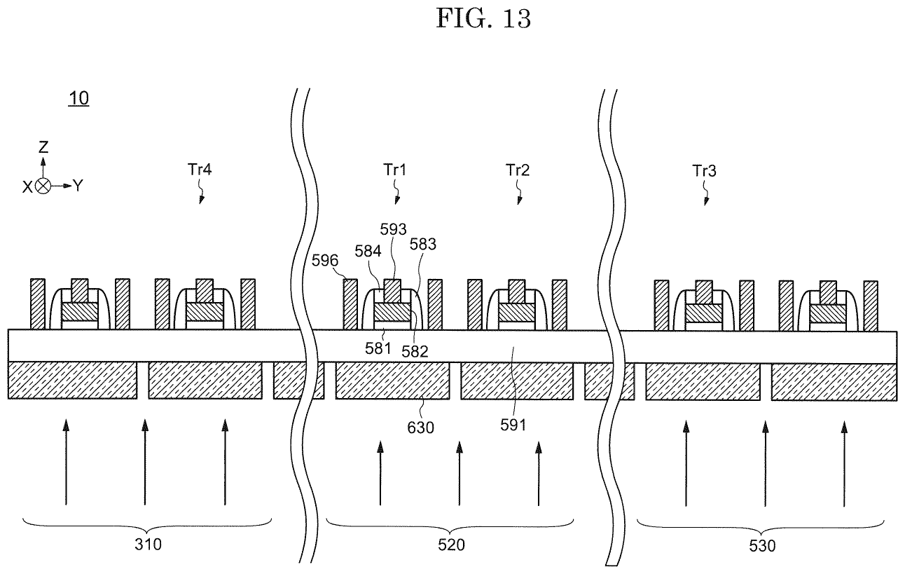

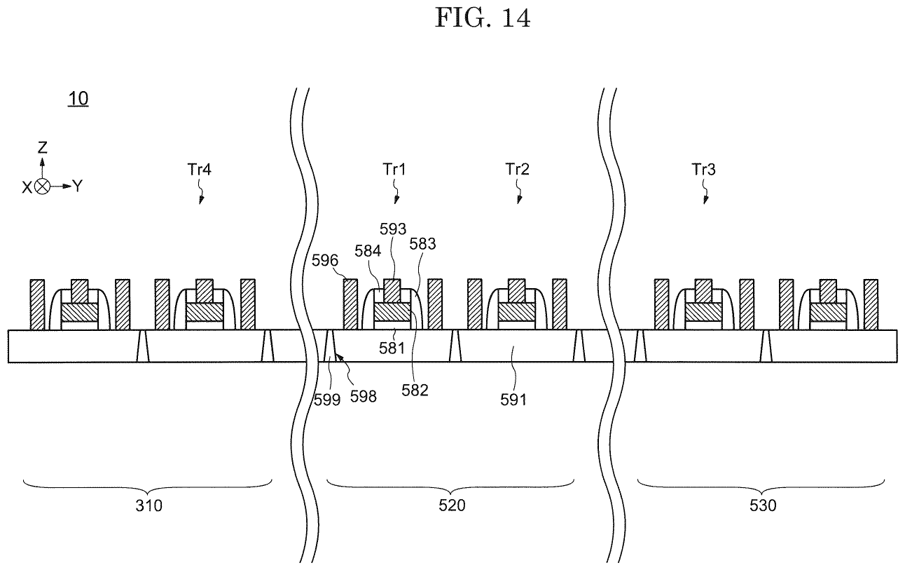

A storage device according to a fourth embodiment will be described with reference to FIG. 12 to FIG. 14. FIG. 12 is a cross-sectional view showing an outline of a storage device according to an embodiment. FIG. 13 and FIG. 14 are cross-sectional views illustrating a method for manufacturing a storage device according to an embodiment. The storage device 10 shown in FIG. 12 is similar to the storage device 10 shown in FIG. 6, but is different from the storage device 10 shown in FIG. 6 in that the shape of the side wall of the trench 598 is different.

### [4-1. Cross-sectional Structure of Transistor Tr]

In FIG. 12, the description of the same configuration as in FIG. 6 will be omitted, and the differences from FIG. 6 will be mainly described. As shown in FIG. 12, the side wall of the trench 598 of the present embodiment is tapered with the slope facing downward. In other words, the distance between the opposing side walls in the trench 598 gradually increases from top to bottom. In other words, referring to FIG. 5, the shape of the trench 598 in the cross-sectional view is a shape in which the width of the trench 598 in the direction parallel to the bonding surface B decreases as the position of the trench 598 approaches the memory cell array 510.

### [4-2. Method for Manufacturing Storage Device 10]

A method for manufacturing the storage device 10 according to the present embodiment will be described with reference to FIG. 13 and FIG. 14. In the first embodiment to the third embodiment, the trench 598 is formed from the above the semiconductor layer 591 before thinning the semiconductor layer 591. However, in the present embodiment, the semiconductor layer 591 is thinned as shown in FIG. 13, and then the trench 598 as shown in FIG. 14 is formed using a mask 630 from below the semiconductor layer 591. As described above, by forming the trench 598 from below the semiconductor layer 591, the trench 598 having the above-described shape can be formed. Thereafter, the insulating layer 599 is formed in the trench 598.

As described above, according to the storage device 10 of the present embodiment, the same effects as those of the storage device 10 of the first embodiment can be obtained.

### 5. Fifth Embodiment

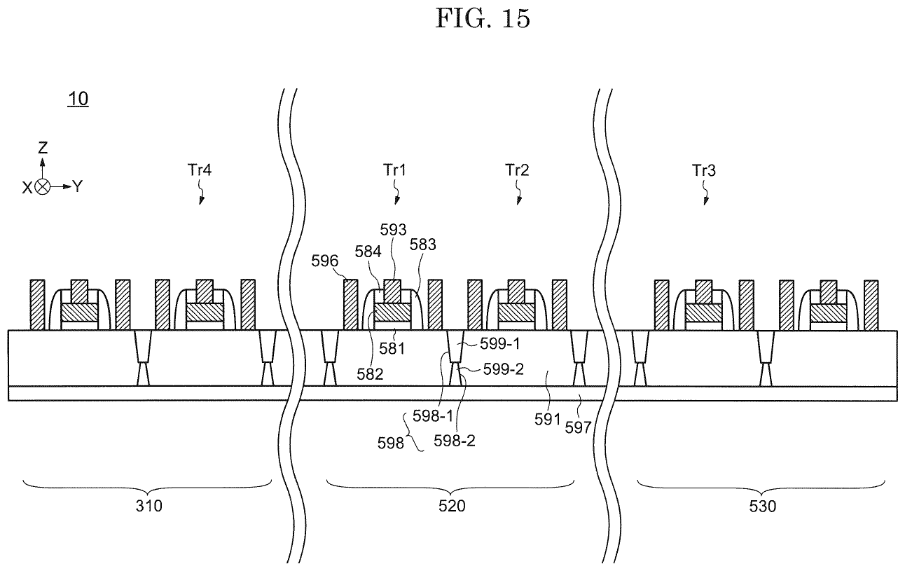

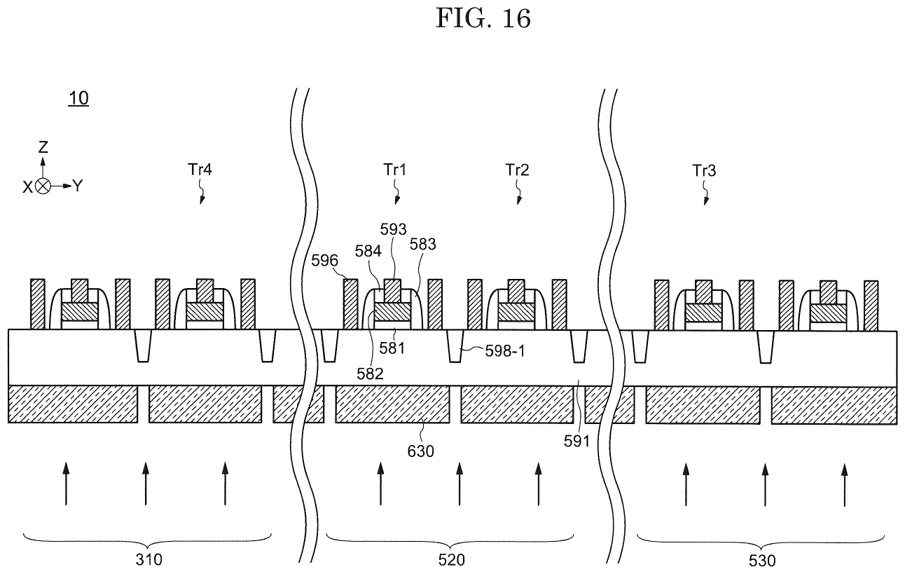

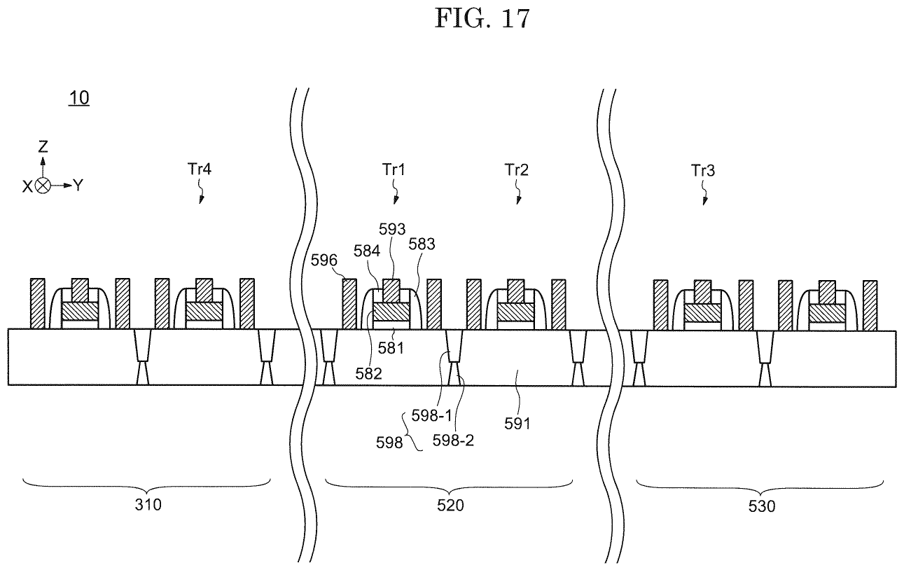

A storage device according to a fifth embodiment will be described with reference to FIG. 15 to FIG. 17. FIG. 15 is a cross-sectional view showing an outline of a storage device according to an embodiment. FIG. 16 and FIG. 17 are cross-sectional views illustrating a method for manufacturing a storage device according to an embodiment. The storage device 10 shown in FIG. 15 is similar to the storage device 10 shown in FIG. 6, but is different from the storage device 10 shown in FIG. 6 in that the shape of the trench 598 is different.

### [5-1. Cross-Section Structure of Transistor Tr]

In FIG. 15, the description of the same configuration as in FIG. 6 will be omitted, and the differences from FIG. 6 will be mainly described. As shown in FIG. 15, the trench 598 of the present embodiment is composed of a first trench 598-1 and a second trench 598-2. An insulating layer 599-1 is arranged in the first trench 598-1, and an insulating layer 599-2 is arranged in the second trench 598-2. Referring to FIG. 5 and FIG. 15, the second trench 598-2 is arranged at a position farther from the memory cell array 510 than the first trench 598-1. The first trench 598-1 is tapered with the inclined surface of the side wall facing upward. In other words, the distance between the opposing side walls in the first trench 598-1 gradually increases from the bottom to the top. The second trench 598-2 is tapered with the inclined surface of the side wall facing downward. In other words, the distance between the opposing side walls in the second trench 598-2 gradually decreases from the bottom to the top.

In FIG. 15, a configuration in which the width of the bottom (lower end portion) of the first trench 598-1 is larger than the width of the bottom (upper end portion) of the second trench 598-2 has been exemplified, but the configuration is not limited to this configuration. For example, the width of the bottom of the first trench 598-1 may be smaller than the width of the bottom of the second trench 598-2, and the width of the bottom of the first trench 598-1 may be the same as the width of the bottom of the second trench 598-2.

### [5-2. Method for Manufacturing Storage Device 10]

A method for manufacturing the storage device 10 according to the present embodiment will be described with reference to FIG. 16 and FIG. 17. First, as shown in FIG. 16, the first trench 598-1 is formed from above the semiconductor layer 591 before thinning the semiconductor layer 591, and the insulating layer 599-1 is formed inside the first trench 598-1. Then thinning of the semiconductor layer 591 is stopped before the lower surface of the semiconductor layer 591 reaches the first trench 598-1. After the thinning is stopped, the second trench 598-2 is formed from below the semiconductor layer 591 as shown in FIG. 17, and the insulating layer 599-2 is formed inside the second trench 598-2. As described above, the first trench 598-1 is formed from above the semiconductor layer 591, and the second trench 598-2 is formed from below the semiconductor layer 591 by using the mask 630, thereby forming the trench 598 having the above-described shape.

As described above, according to the storage device 10 of the present embodiment, the same effects as those of the storage device 10 of the first embodiment can be obtained.

Although the present disclosure has been described above with reference to the drawings, the present disclosure is not limited to the embodiments described above and can be modified as appropriate without departing from the spirit of the present disclosure. For example, the addition, deletion, or design change of components as appropriate by those skilled in the art based on a storage device of the present embodiment are also included in the scope of the present disclosure as long as they are provided with the gist of the present disclosure. Furthermore, each of the embodiments described above as an embodiment of the present invention can be appropriately combined and implemented as long as no contradiction is caused.

Further, it is understood that, even if the effect is different from those provided by each of the above-described embodiments, the effect obvious from the description in the specification or easily predicted by persons ordinarily skilled in the art is apparently derived from the present disclosure.

What is claimed is:

1. A storage device comprising:
a memory cell array; and
a peripheral circuit,
wherein
the memory cell array includes:
a first memory cell;
a second memory cell;
a first word line connected to the first memory cell;
a second word line connected to the second memory cell;
a bit line connected to the first memory cell and the second memory cell;
a first connecting electrode;
a second connecting electrode; and
a third connecting electrode,
the peripheral circuit includes:
a first circuit;
a second circuit;
a third circuit connected to the first circuit and the second circuit and configured to send/receive a signal to/from an external device;
a fourth connecting electrode bonded to the first connecting electrode;
a fifth connecting electrode bonded to the second connecting electrode; and
a sixth connecting electrode bonded to the third connecting electrode,
the first circuit includes:
a first transistor and a second transistor including a first semiconductor layer;
a trench;
a first insulating layer; and
a second insulating layer,
wherein
the first transistor is connected to the first word line via the first connecting electrode and the fourth connecting electrode,
the second transistor is connected to the second word line via the second connecting electrode and the fifth connecting electrode,
the trench is arranged in the first semiconductor layer between the first transistor and the second transistor,
the first insulating layer is formed in the trench,
the second circuit is connected to the bit line via the third connecting electrode and the sixth connecting electrode, and
the second insulating layer is in contact with the first insulating layer at an end portion of the first insulating layer on a side further from the memory cell array.

2. The storage device according to claim 1, wherein the second insulating layer is in contact with the first insulating layer on a surface of the first insulating layer on a side further from the memory cell array.

3. The storage device according to claim 1, wherein
the first transistor and the second transistor are aligned in a first direction, and
a width of the trench in the first direction is 200 nm or less.

4. The storage device according to claim 3, wherein a depth of the trench is 300 nm or less.

5. The storage device according to claim 1, wherein
the second circuit includes a third transistor,
the third transistor is connected to the bit line via the third connecting electrode and the sixth connecting electrode,
the third transistor includes a second semiconductor layer functioning as a channel, and
a surface of the second semiconductor layer on a side further from the memory cell array is covered with the second insulating layer.

6. The storage device according to claim 5, wherein
the second circuit includes:
a sense amplifier circuit configured to determine data stored in a memory cell to be read; and
a latch circuit configured to store a result determined by the sense amplifier circuit, and
the latch circuit is constituted by the third transistor.

7. The storage device according to claim 6, wherein the third transistor is a floating body cell.

8. The storage device according to claim 1, wherein
the third circuit includes a fourth transistor,
the fourth transistor includes a third semiconductor layer functioning as a channel, and
a surface of the third semiconductor layer on a side further from the memory cell array is covered with the second insulating layer.

9. The storage device according to claim 1, wherein
the second circuit includes a third transistor,
the third transistor is connected to the bit line via the third connecting electrode and the sixth connecting electrode,
the third transistor includes a second semiconductor layer functioning as a channel,
a surface of the second semiconductor layer on a side further from the memory cell array is covered with the second insulating layer,
the third circuit includes a fourth transistor,
the fourth transistor includes a third semiconductor layer functioning as a channel,
a surface of the third semiconductor layer on a side further from the memory cell array is covered with the second insulating layer, and
a thickness of the first semiconductor layer, a thickness of the second semiconductor layer and a thickness of the third semiconductor layer are the same.

10. The storage device according to claim 1, wherein
the second circuit includes a third transistor and a third insulating layer,
the third transistor is connected to the bit line via the third connecting electrode and the sixth connecting electrode,
the third transistor includes a second semiconductor layer functioning as a channel,
a surface of the second semiconductor layer on a side further from the memory cell array is covered with the third insulating layer,
the third circuit includes a fourth transistor and a fourth insulating layer,
the fourth transistor includes a third semiconductor layer functioning as a channel,
a surface of the third semiconductor layer on a side further from the memory cell array is covered with the fourth insulating layer, and
at least one of a thickness of the first semiconductor layer, a thickness of the second semiconductor layer, and a thickness of the third semiconductor layer is smaller than the thicknesses of the other semiconductor layers.

11. The storage device according to claim 1, wherein
the second circuit includes a third transistor and a third insulating layer,
the third transistor is connected to the bit line via the third connecting electrode and the sixth connecting electrode,
the third transistor includes a second semiconductor layer functioning as a channel,
a surface of the second semiconductor layer on a side further from the memory cell array is covered with the third insulating layer,
the third circuit includes a fourth transistor and a fourth insulating layer,
the fourth transistor includes a third semiconductor layer functioning as a channel,
a surface of the third semiconductor layer on a side further from the memory cell array is covered with the fourth insulating layer, and
a thickness of the first semiconductor layer is the same as a thickness of the second semiconductor layer and a thickness of the third semiconductor layer.

12. The storage device according to claim 1, wherein
the first semiconductor layer is composed of a plurality of different semiconductor layers, and
a bottom of the trench is present in any one of the plurality of semiconductor layers.

13. The storage device according to claim 12, wherein
the first semiconductor includes:
a silicon layer on a side closer to the memory cell array; and
a silicon germanium layer on a side further from the memory cell array.

14. The storage device according to claim 12, wherein
the first semiconductor includes:
a silicon layer on a side closer to the memory cell array; and
a silicon oxide layer on a side further from the memory cell array.

15. The storage device according to claim 1, wherein a shape of the trench is a shape that a width of the trench in a direction parallel to a bonding surface between the memory cell array and the peripheral circuit increases as a position of the trench approaches the memory cell array.

16. The storage device according to claim 1, wherein a shape of the trench is a shape that a width of the trench in a direction parallel to a main surface of the peripheral circuit decreases as a position of the trench approaches the memory cell array.

17. The storage device according to claim 1, wherein
the trench includes a first trench and a second trench arranged in a position further from the memory cell array than the first trench,
a shape of the first trench is a shape that a width of the first trench in a direction parallel to a main surface of the peripheral circuit increases as a position of the trench the first trench approaches the memory cell array, and
a shape of the second trench is a shape that a width of the second trench in the direction parallel to the main surface of the peripheral circuit decreases as a position of the trench the second trench approaches the memory cell array.

18. The storage device according to claim 1, further comprising a control circuit configured to control the first circuit, the second circuit and the third circuit,
wherein the control circuit applies a voltage of 20 V or more and 30 V or less to the first word line and the second word line in the case of driving the first memory cell and the second memory cell.
